(19) United States
(12) Patent Application Publication
(10) Pub. No.: US 2024/0128402 A1
(43) Pub. Date: Apr. 18, 2024

(54) LIGHT-EMITTING DEVICE AND LIGHT-EMITTING DEVICE ARRAY INCLUDING THE SAME

(71) Applicant: SAMSUNG ELECTRONICS CO., LTD., Suwon-si (KR)

(72) Inventors: Yongmin KWON, Suwon-si (KR); Donggun LEE, Suwon-si (KR); Punjae CHOI, Suwon-si (KR); Youngjin CHOI, Suwon-si (KR)

(73) Assignee: SAMSUNG ELECTRONICS CO., LTD., Suwon-si (KR)

(21) Appl. No.: 18/241,589

(22) Filed: Sep. 1, 2023

(30) Foreign Application Priority Data
Oct. 17, 2022 (KR) 10-2022-0133620

(51) Int. Cl. H01L 33/08; H01L 33/06; H01L 33/10; H01L 33/38

(52) U.S. Cl. CPC H01L 33/08; H01L 33/06; H01L 33/10; H01L 33/382; H01L 33/385

(57) ABSTRACT

A light-emitting device include an emission layer configured to emit white light, and a reflective layer at least partially surrounding side surfaces of the emission layer, where the emission layer includes a first conductivity-type semiconductor layer, a second conductivity-type semiconductor layer on the first conductivity-type semiconductor layer, a first active layer between the first conductivity-type semiconductor layer and the second conductivity-type semiconductor layer, the first active layer configured to emit blue light, and a second active layer between the first conductivity-type semiconductor layer and the second conductivity-type semiconductor layer, the second active layer configured to emit yellow light.

### CROSS-REFERENCE TO RELATED APPLICATIONS

This application is based on and claims priority to Korean Patent Application No. 10-2022-0133620, filed on Oct. 17, 2022, in the Korean Intellectual Property Office, the disclosure of which is incorporated by reference herein in its entirety.

### BACKGROUND

### 1. Field

The disclosure relates to a light-emitting device and a light-emitting device array.

### 2. Description of Related Art

Demand for using a semiconductor light-emitting device in various lighting devices such as vehicle headlamps or indoor lighting is increasing. For example, when a light source module including a plurality of light-emitting device chips is used, an intelligent lighting system for implementing various lighting modes according to surrounding conditions by individually controlling each light-emitting device chip has been proposed. However, in order to implement intelligent lighting systems, optical characteristics and reliability of light-emitting devices need to be improved.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a compact-size light-emitting device emitting white light through an active layer emitting light of different wavelengths.

One or more example embodiments also provide a light-emitting device array in which optical interference between light-emitting devices adjacent to each other may be prevented without barriers.

Additional aspects will be set forth in part in the description which follows and, in part, will be apparent from the description, or may be learned by practice of the presented embodiments.

According to an aspect of an example embodiment, a light-emitting device may include an emission layer configured to emit white light, and a reflective layer at least partially surrounding side surfaces of the emission layer, where the emission layer includes a first conductivity-type semiconductor layer, a second conductivity-type semiconductor layer on the first conductivity-type semiconductor layer, a first active layer between the first conductivity-type semiconductor layer and the second conductivity-type semiconductor layer, the first active layer configured to emit blue light, and a second active layer between the first conductivity-type semiconductor layer and the second conductivity-type semiconductor layer, the second active layer configured to emit yellow light.

According to an aspect of an example embodiment, a light-emitting device array may include a plurality of emission layers spaced apart from each other in a first direction, each of the plurality of emission layers being configured to emit white light and a reflective layer at least partially surrounding side surfaces of the plurality of emission layers, where each of the plurality of emission layers includes a first conductivity-type semiconductor layer, a second conductivity-type semiconductor layer on the first conductivity-type semiconductor layer, a first active layer between the first conductivity-type semiconductor layer and the second conductivity-type semiconductor layer, the first active layer configured to emit light having a first peak wavelength, and a second active layer between the first conductivity-type semiconductor layer and the second conductivity-type semiconductor layer, the second active layer configured to emit light having a second peak wavelength that is different from the first peak wavelength.

According to an aspect of an example embodiment, a light-emitting device array may include plurality of emission layers spaced apart from each other in a first direction, each of the plurality of emission layers including a first conductivity-type semiconductor layer, a first active layer configured to emit blue light, a second active layer configured to emit yellow light, and a second conductivity-type semiconductor layer, where the first conductivity-type semiconductor layer, the first active layer, the second active layer and the second conductivity-type semiconductor layer are sequentially stacked, a reflective layer at least partially surrounding side surfaces of the plurality of emission layers, a plurality of first electrodes each contacting different emission layers among the plurality of emission layers, and a plurality of second electrodes each contacting different emission layers among the plurality of emission layers, where each of the plurality of emission layers has a length of about 0.1 μm to about 100 μm in the first direction, and a length of about 0.1 μm to about 100 μm in a second direction perpendicular to the first direction, the plurality of emission layers are spaced apart from each other in the first direction by about 1 μm to about 15 μm, positions at which the plurality of first electrodes respectively contact the plurality of emission layers are of a same first height, and positions at which the plurality of second electrodes respectively contact the plurality of emission layers are of a same second height.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view of a light-emitting device according to an embodiment;

FIG. 2 is a graph showing a wavelength band of light emitted from the light-emitting device of FIG. 1 according to an embodiment;

FIG. 3 is a cross-sectional view of a region marked “III” in FIG. 1 according to an embodiment;

FIGS. 4, 5 and 6 are cross-sectional views of a light-emitting device according to an embodiment;

FIG. 7 is a cross-sectional view of a light-emitting device array according to an embodiment;

FIG. 8 is a diagram of the light-emitting device array of FIG. 7 according to an embodiment;

FIGS. 9 and 10 are cross-sectional views of a light-emitting device array according to an embodiment;

FIGS. 11, 12, 13, 14 and 15 are diagrams of lighting devices including a light-emitting device according to an embodiment;

FIG. 16 is a diagram of a control network system for an indoor lighting device including a semiconductor light-emitting device according to an embodiment; and

FIG. 17 is a diagram of a network system including a semiconductor light-emitting device according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

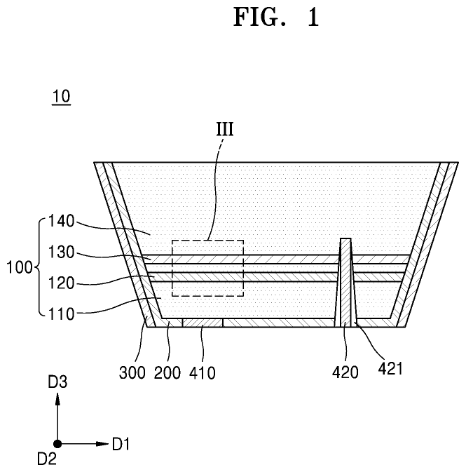

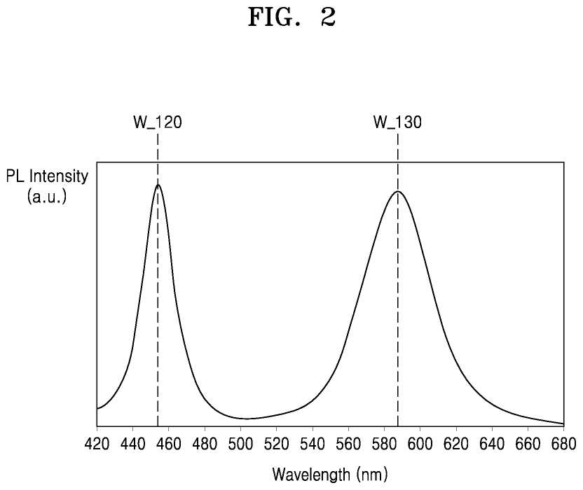

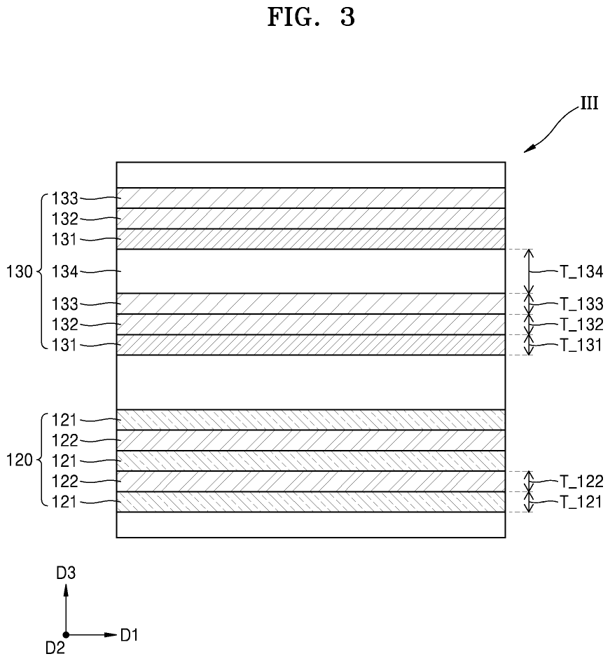

FIG. 1 is a cross-sectional view of a light-emitting device according to an embodiment. FIG. 2 is a graph showing a wavelength band of light emitted from the light-emitting device of FIG. 1 according to an embodiment. FIG. 3 is a cross-sectional view of a region marked “III” in FIG. 1 according to an embodiment.

Referring to FIGS. 1 to 3, a light-emitting device 10 may include an emission layer 100, a passivation layer 200, a reflective layer 300, a first electrode 410, and a second electrode 420.

The emission layer 100 of the light-emitting device 10 may include a first conductivity-type semiconductor layer 110, a first active layer 120, a second active layer 130, and a second conductivity-type semiconductor layer 140. The emission layer 100 may emit white light from light to be emitted from the first active layer 120 and the second active layer 130. In some embodiments, the first conductivity-type semiconductor layer 110, the first active layer 120, the second active layer 130, and the second conductivity-type semiconductor layer 140 may be sequentially stacked.

The first conductivity-type semiconductor layer 110 of the emission layer 100 may include a nitride semiconductor layer having a composition of p-type InₓAl_{y}Ga_{(1-x-y)}N (0≤x<1, 0≤y<1, 0≤x+y<1), and for example, the p-type impurity may be magnesium (Mg).

In some embodiments, the first conductivity-type semiconductor layer 110 may include an electron-blocking layer, a low-concentration p-type GaN layer, and a high-concentration p-type GaN layer which is provided as a contact layer. For example, the electron-blocking layer may have a structure in which a plurality of InₓAl_{y}Ga_{(1-x-y)}N layers (0≤x, y≤1, 0≤x+y≤1), and each of which may have a thickness of about 5 nm to about 100 nm and different compositions from each other, or each of which may have different impurity contents, may be alternately stacked, or may include a single layer including Al_{y}Ga_{(1-y)}N (0<y≤1). An energy band gap of the electron-blocking layer may decrease as the electron-blocking layer is further away from the first active layer 120 and the second active layer 130. For example, an Al composition of the electron-blocking layer may decrease as the electron-blocking layer is further away from the first active layer 120 and the second active layer 130.

The second conductivity-type semiconductor layer 140 of the emission layer 100 may be located on the second active layer 130. The second conductivity-type semiconductor layer 140 may include a nitride semiconductor having a composition of n-type InₓAl_{y}Ga_{(1-x-y)}N(0≤x<1, 0≤y<1, 0≤x+y<1), and for example, the n-type impurity may be silicon (Si). For example, the second conductivity-type semiconductor layer 140 may include GaN containing n-type impurities.

In some embodiments, the second conductivity-type semiconductor layer 140 may include a second conductivity-type semiconductor contact layer and a current diffusion layer. An impurity concentration of the second conductivity-type semiconductor contact layer may be in a range of about 2×10¹⁸ cm⁻³ to about 9×10¹⁹ cm⁻³. The second conductivity-type semiconductor contact layer may have a thickness of about 1 μm to about 5 μm. The current diffusion layer may have a structure in which a plurality of InxAlyGa(1-x-y)N(0≤x, y≤1, 0≤x+y≤1) layers having different compositions or different impurity contents are alternately stacked. For example, the current diffusion layer may have an n-type superlattice structure in which an n-type GaN layer and/or an AlₓIn_{y}Ga_{z}N layer (0≤x, y, z≤1, x+y+z≠0) each having a thickness of about 1 nm to about 500 nm are alternately stacked. An impurity concentration of the current diffusion layer may be about 2×10¹⁸ cm⁻³ to about 9×10¹⁹ cm⁻³.

The first active layer 120 of the emission layer 100 may be arranged between the first conductivity-type semiconductor layer 110 and the second conductivity-type semiconductor layer 140, and may generate certain energy by recombination of electrons and holes. In some embodiments, the first active layer 120 may emit blue light. In an embodiment, a peak wavelength W_120 of the blue light of the first active layer 120 may be in a range of about 425 nm to about 480 nm.

The first active layer 120 may have a multi-quantum well (MQW) structure in which quantum well layers 121 and quantum barrier layers 122 are alternately stacked. For example, the quantum well layer 121 and the quantum barrier layer 122 may include InₓAl_{y}Ga (1-x-y)N(0≤x, y≤1, 0≤x+y≤1) having different compositions. For example, the quantum well layer 121 may include InₓGa₍₁₋ₓ₎N(0≤x≤1), and the quantum barrier layer 122 may include GaN or AlGaN. Thicknesses of the quantum well layer 121 and the quantum barrier layer 122 may each be in a range of about 1 nm to about 50 nm. The first active layer 120 is not limited to the MQW structure and may have a single quantum well structure.

In some embodiments, the quantum well layer 121 of the first active layer 120 may include InₓGa₍₁₋ₓ₎N(0.1≤x≤0.3) and the quantum barrier layer 122 may include GaN. A thickness T_121 of the quantum well layer 121 may be in a range of about 1 nm to about 5 nm. A thickness T_122 of the quantum barrier layer 122 may be in a range of about 3 nm to about 10 nm.

The second active layer 130 of the emission layer 100 may be arranged between the first conductivity-type semiconductor layer 110 and the second conductivity-type semiconductor layer 140, and may generate certain energy by recombination of electrons and holes. In some embodiments, the second active layer 130 may emit yellow light. In an embodiment, a peak wavelength W_130 of the yellow light of the second active layer 130 may be in a range of about 520 nm to about 600 nm.

While the first active layer 120 emitting blue light and the second active layer 130 emitting yellow light have been described with reference to FIGS. 1 to 3, light emitted from the first active layer 120 and the second active layer 130 according to the disclosure is not limited thereto, and the first active layer 120 and the second active layer 130 may each emit light having different peak wavelengths.

The second active layer 130 may have an MQW structure in which a quantum well layer 131, an intermediate lattice layer 132, and quantum barrier layers 133 and 134 are sequentially stacked.

For example, the quantum well layer 131 and the quantum barrier layers 133 and 134 may include InₓAl_{y}Ga_{(1-x-y)}N(0≤x, y≤1, 0≤x+y)≤1) having different compositions. For example, the quantum well layer 131 may include InₓGa₁₋ₓN (0≤x≤1), and the quantum barrier layers 133 and 134 may include GaN or AlGaN. The intermediate lattice layer 132 may be formed between the quantum well layer 131 and the quantum barrier layers 133 and 134 and may include AlGaN or InGaN. The second active layer 130 is not limited to the MQW structure and may have a single quantum well structure.

The second active layer 130 may emit long-wavelength light having a peak wavelength of 500 nm or more through the intermediate lattice layer 132. That is, the second active layer 130 may emit yellow light through the intermediate lattice layer 132.

In some embodiments, the quantum well layer 131 of the second active layer 130 may include InₓGa₍₁₋ₓ₎N(0.2≤x≤0.5), and the quantum barrier layers 133 and 134 may include Al_{y}Ga_{(1-y)}N(0.2≤y≤0.5) The intermediate lattice layer 132 may include In_{x′}Ga_{(1-x′)}N (0≤x′≤0.2) or Al_{y′}Ga(1-y′)N(0≤y′≤0.2). A thickness T_131 of the quantum well layer 131 may be in a range of about 3 nm to about 7 nm. A thickness T_133 of the first quantum barrier layer 133 may be in a range of about 1 nm to about 10 nm. A thickness T_132 of the intermediate lattice layer 132 may be in a range of about 1 nm to about 5 nm.

In some embodiments, the quantum well layer 131 of the second active layer 130 may include InₓGa₍₁₋ₓ₎N(0.2≤x≤0.5), and the intermediate lattice layer 132 may include In_{x′}Ga_{(1-x′)}N(0≤x′≤0.2) or Al_{y′}Ga_{(1-y′)}N(0≤y′≤0.2). The quantum barrier layers 133 and 134 may include a first quantum barrier layer 133 including Al_{y}Ga_{(1-y)}N(0.2≤y≤0.5) and a second quantum barrier layer 134 including GaN. A thickness T_131 of the quantum well layer 131 may be in a range of about 3 nm to about 7 nm. The thickness T_132 of the intermediate lattice layer 132 may be in a range of about 1 nm to about 5 nm. A thickness T_133 of the first quantum barrier layer 133 may be in a range of about 1 nm to about 10 nm. A thickness T_134 of the second quantum barrier layer 134 may be in a range of about 5 nm to about 50 nm.

The light-emitting device 10 may emit white light through the first active layer 120 emitting blue light and the second active layer 130 emitting yellow light. That is, the light-emitting device 10 may emit white light without a phosphor. As the light-emitting device 10 may emit white light without a phosphor, the size of the light-emitting device 10 may be reduced without being limited by a phosphor process. As the light-emitting devices 10 have a reduced size, the number of the light-emitting devices 10 that may be arranged within the same area is increased, and also, image quality may be improved because there is no decrease in contrast ratio due to the reduced size.

The passivation layer 200 of the light-emitting device 10 may be located on side surfaces and a lower surface of the emission layer 100. The passivation layer 200 may cover the side surfaces of the emission layer 100, thereby preventing deterioration of the light extraction efficiency of the emission layer 100. According to embodiments, the passivation layer 200 may prevent non-emission recombination in the first active layer 120 or the second active layer 130.

According to embodiments, the passivation layer 200 may include an insulating material. The passivation layer 200 may include oxide and nitride. According to embodiments, the passivation layer 200 may include any one of aluminum oxide, aluminum nitride, silicon oxide, and silicon nitride. According to embodiments, the passivation layer 200 may include thermal oxide. According to embodiments, the passivation layer 200 may include any one of SiO₂ and Al₂O₃, and thus may extend conformally. According to embodiments, a thickness of the passivation layer 200 may be in a range of about 1 nm to about 1000 nm.

The reflective layer 300 of the light-emitting device 10 may be located on the side surfaces of the emission layer 100. The reflective layer 300 may cover (e.g., at least partially cover, at least partially surrounds, etc.) the side surfaces of the emission layer 100. In some embodiments, the reflective layer 300 may cover an entire area of the side surfaces of the emission layer 100. That is, an upper surface of the reflective layer 300 may be higher than upper surfaces of the first active layer 120 and the second active layer 130 of the emission layer 100, and thus, light emitted from the first active layer 120 and the second active layer 130 may be reflected by the upper surface of the reflective layer 300. In some embodiments, the reflective layer 300 may be located on the side surfaces and the lower surface of the emission layer 100 to reflect light emitted from the emission layer 100 to an upper surface of the emission layer 100.

In some embodiments, the reflective layer 300 may include a material having high reflectivity with respect to yellow light or blue light. In embodiments, the reflective layer 300 may include a metal layer including Ag, Al, Ni, Cr, Au, Pt, Pd, Sn, W, Rh, Ir, Ru, Mg, Zn, Ti, and a combination thereof. In other embodiments, the reflective layer 300 may include a resin layer such as polyphthalamide (PPA) containing a metal oxide such as titanium oxide or aluminum oxide. In other embodiments, the reflective layer 300 may include a distributed Bragg reflector (DBR) layer. For example, the DBR layer may have a structure in which a plurality of insulating films having different refractive indices are repeatedly stacked several times to hundreds of times. The insulating film included in the DBR layer may include an oxide or nitride such as SiO₂, SiN, SiOₓN_{y}, TiO₂, Si₃N₄, Al₂O₃, TiN, AlN, ZrO₂, TiAlN, TiSiN, HfO₂, or a combination thereof.

The first electrode 410 of the light-emitting device 10 may contact the first conductivity-type semiconductor layer 110. In some embodiments, the first electrode 410 may be arranged on a lower surface of the first conductivity-type semiconductor layer 110. The passivation layer 200 may be arranged between the first electrode 410 and the second electrode 420 on the lower surface of the first conductivity-type semiconductor layer 110, and may electrically insulate the first electrode 410 from the second electrode 420.

The second electrode 420 of the light-emitting device 10 may contact the second conductivity-type semiconductor layer 140. In some embodiments, the second electrode 420 may be arranged to be connected to the second conductivity-type semiconductor layer 140 within an opening penetrating the first active layer 120, the second active layer 130, and the first conductivity-type semiconductor layer 110. A first insulating layer 421 may be disposed on an inner wall of the opening to electrically insulate the second electrode 420 from the first active layer 120, the second active layer 130, and the first conductivity-type semiconductor layer 110. In some embodiments, the first insulating layer 421 may include silicon oxide, silicon nitride, or polyimide.

In some embodiments, the first electrode 410 and the second electrode 420 may contact the emission layer 100. The first electrode 410 and the second electrode 420 may include Ag, Al, Ni, Cr, Au, Pt, Pd, Sn, W, Rh, Ir, Ru, Mg, Zn, Ti, and a combination thereof. The first electrode 410 and the second electrode 420 may include a metal material having relatively high reflectivity.

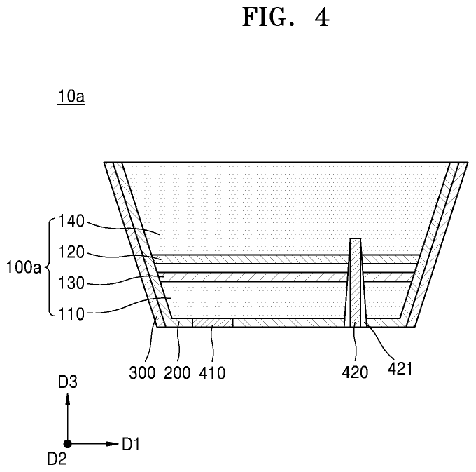

FIG. 4 is a cross-sectional view of a light-emitting device according to an embodiment.

Referring to FIG. 4, the light-emitting device 10a of FIG. 4 may include similar aspects as those of the light-emitting device of FIG. 1 (10 in FIG. 1), and repeated descriptions may be omitted.

The first active layer 120 and the second active layer 130 of the light-emitting device 10a may be located between the first conductivity-type semiconductor layer 110 and the second conductivity-type semiconductor layer 140. In some embodiments, the first active layer 120 may emit blue light and the second active layer 130 may emit yellow light.

In some embodiments including the emission layer 100 in FIG. 1, the second active layer 130 may be located on the first active layer 120. That is, the second active layer 130 emitting yellow light may be located at a higher position than the first active layer 120 emitting blue light.

In some embodiments including an emission layer 100a, the first active layer 120 may be located on the second active layer 130. That is, the first active layer 120 emitting blue light may be located at a higher position than the second active layer 130 emitting yellow light.

The light-emitting device 10a may emit white light by a combination of lights emitted from the first active layer 120 and the second active layer 130. In the emission layer 100a, the order of the first active layer 120 and the second active layer 130 may vary according to the intensity of light emitted by the first active layer 120 and the intensity of light emitted by the second active layer 130.

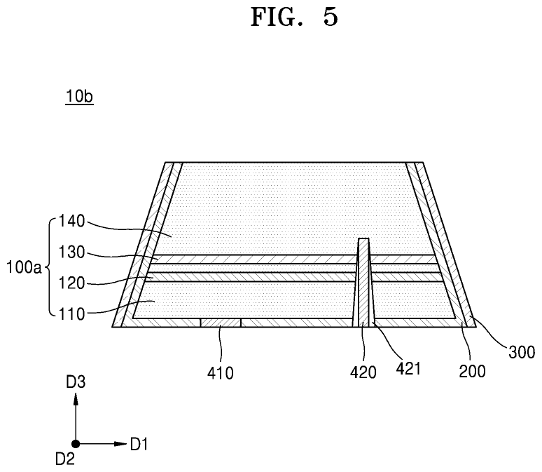

FIG. 5 is a cross-sectional view of a light-emitting device according to an embodiment.

Referring to FIG. 4, the light-emitting device 10b of FIG. 5 may include similar aspects as those of the light-emitting device of FIG. 1 (10 in FIG. 1), and repeated descriptions may be omitted.

The emission layer 100a of the light-emitting device 10b may have a width that varies. That is, the emission layer 100a may have a width varying toward an upper surface thereof. In some embodiments, the emission layer 100a may have a tapered shape having a width increasing toward an upper surface thereof. In some embodiments, the emission layer 100a may have a tapered shape having a width decreasing toward an upper surface thereof. In some embodiments, in a process of etching side surfaces of the emission layer 100a, the side surface of the emission layer 100a may be inclined. In some embodiments, in a process of etching the side surface of the emission layer 100a, the side surface of the emission layer 100a may be perpendicular to an upper surface and a lower surface of the emission layer 100.

In some embodiments, when etching is performed on the upper surface of the emission layer 100a, the emission layer 100a may have a shape in which the upper surface has a smaller area than the lower surface. When etching is performed on the upper surface of the emission layer 100a, an angle between the side surfaces and the lower surface of the emission layer 100a may be in a range of about 60 degrees to about 70 degrees. When etching is performed on the upper surface of the emission layer 100a, portions of the first active layer 120 and the second active layer 130 to be removed may be reduced. As the first active layer 120 and the second active layer 130 of the emission layer 100a have a relatively wide area, the light-emitting device 10b may have relatively high contrast ratio and brightness.

In some embodiments, when etching is performed on the lower surface of the emission layer 100a, the emission layer 100a may have a shape in which the upper surface has a larger area than the lower surface. When etching is performed on the lower surface of the emission layer 100a, an angle between the side surfaces and the lower surface of the emission layer 100a may be in a range of about 70 degrees to about 89 degrees. Etching the lower surface of the emission layer 100 may facilitate the production of the light-emitting device 10b.

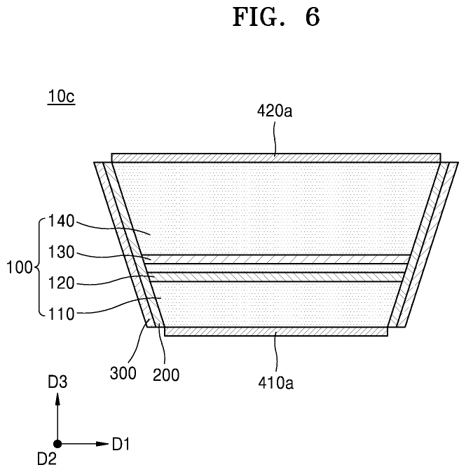

FIG. 6 is a cross-sectional view of a light-emitting device according to an embodiment.

Referring to FIG. 6, the light-emitting device 10c of FIG. 6 may include similar aspects as those of the light-emitting device of FIG. 1 (10 in FIG. 1), and repeated descriptions may be omitted.

A first electrode 410a of the light-emitting device 10c may contact the emission layer 100. The first electrode 410a may contact the first conductivity-type semiconductor layer 110. In some embodiments, the first electrode 410a may contact the whole area (e.g., may contact an entire area, an entire surface area, and entire exposed area, etc.) of a lower surface of the first conductivity-type semiconductor layer 110. As referred to herein, the “whole area” may refer to an entirety of an area of a surface of a layer, an amount of area corresponding to an exposed portion or surface of a layer, an entire amount of area that is required to be contacted for functionality (i.e., in some embodiments, the entire area may not need to be contacted by an electrode to ensure functionality) or other area amounts of surfaces. In some embodiments, an electrode may contact an entire area of a surface of a layer, a partial area of a surface of a layer, or combinations thereof, without departing from the scope of the disclosure.

A second electrode 420a of the light-emitting device 10c may contact the emission layer 100. The second electrode 420a may contact the second conductivity-type semiconductor layer 140. In some embodiments, the second electrode 420a may be contact the whole area of an upper surface of the second conductivity-type semiconductor layer 140.

In FIG. 6, the first electrode 410a contacting the first conductivity-type semiconductor layer 110 over the whole area, and the second electrode 420a contacting the second conductivity-type semiconductor layer 140 over the whole area are illustrated, but the disclosure is not limited thereto, and only one of the first electrode 410a or the second electrode 420a may contact a conductivity-type semiconductor layer over the whole area.

The first electrode 410a may contact the lower surface of the first conductivity-type semiconductor layer 110 and may be electrically connected to the first conductivity-type semiconductor layer 110. The second electrode 420a may contact the upper surface of the second conductivity-type semiconductor layer 140 and may be electrically connected to the second conductivity-type semiconductor layer 140. The first electrode 410a may have a plain shape extending along a lower surface of the emission layer 100 and may reflect light emitted from the emission layer 100 in a direction toward the upper surface of the emission layer 100. The second electrode 420a may be configured to transmit through light emitted from the emission layer 100. That is, the second electrode 420a may be substantially transparent to the light emitted from the emission layer 100. For example, the second electrode 420a may include indium tin oxide (ITO). The light emitted from the emission layer 100 may pass through the second electrode 420a and may be emitted to the outside. As the second electrode 420a is located on the upper surface of the second conductivity-type semiconductor layer 140, the manufacture of the light-emitting device 10c may be facilitated.

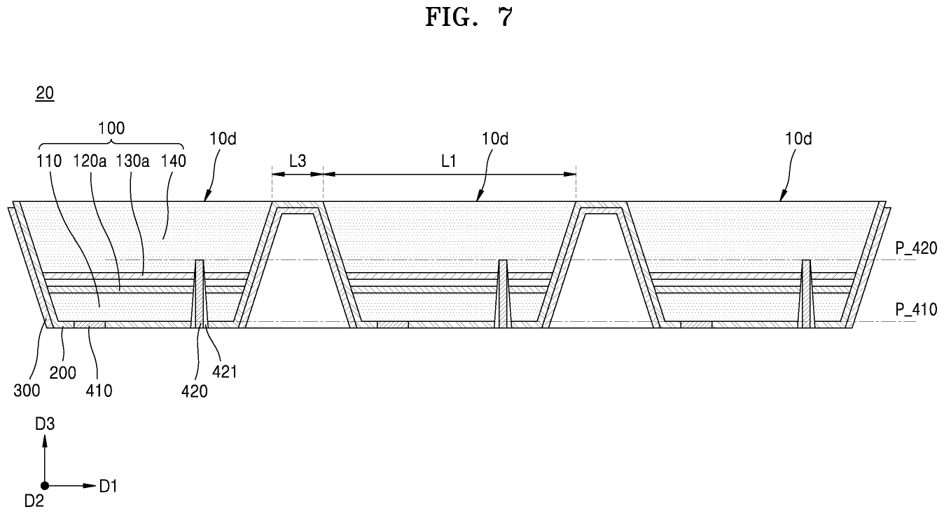

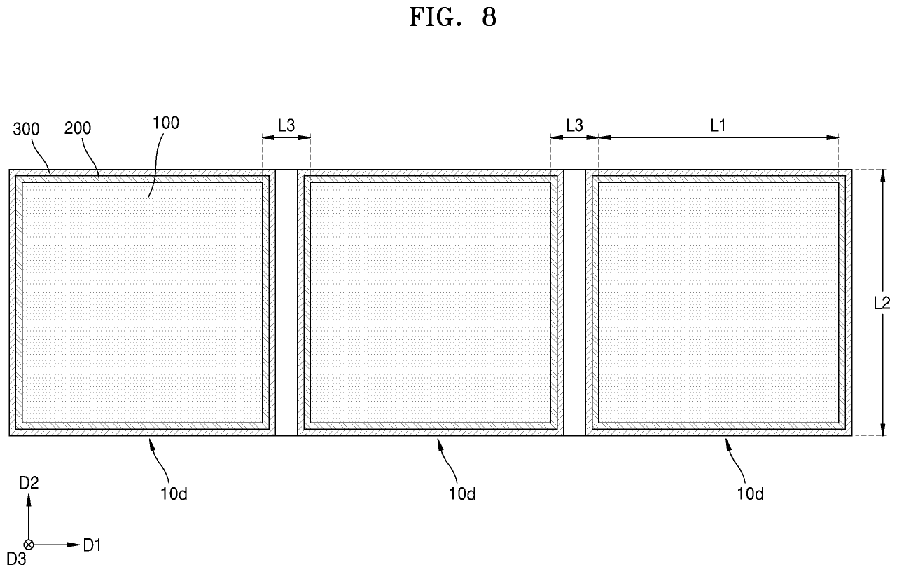

FIG. 7 is a cross-sectional view of a light-emitting device array according to an embodiment. FIG. 8 is a diagram of the light-emitting device array of FIG. 7 according to an embodiment. FIG. 8 is a bottom view of the light-emitting device array of FIG. 7.

Referring to FIGS. 7 and 8, a light-emitting device array 20 may include a plurality of emission layers 100, a reflective layer 300, a passivation layer 200, a first electrode 410, and a second electrode 420. Hereinafter, the repeated description of the light-emitting device array 20 of FIGS. 7 and 8 with respect to the light-emitting device of FIG. 1 (10 in FIG. 1) may be omitted.

The plurality of emission layers 100 of the light-emitting device array 20 may be arranged to be spaced apart from each other in a first direction D1. Each of the plurality of emission layers 100 may emit white light. That is, the emission layers 100 capable of emitting white light may be arranged in a line. In other words, the light-emitting device array 20 may have a shape in which the light-emitting devices 10d including the emission layer 100 and the reflective layer 300 are arranged apart from each other in the first direction D1.

The plurality of emission layers 100 of the light-emitting device array 20 may each include a first conductivity-type semiconductor layer 110, a second conductivity-type semiconductor layer 140, a first active layer 120a, and a second active layer 130a.

The first conductivity-type semiconductor layer 110 of the emission layer 100 may include a nitride semiconductor layer having a composition of p-type InₓAl_{y}Ga_{(1-x-y)}N (0≤x<1, 0≤y<1, 0≤x+y<1), and for example, the p-type impurity may be magnesium (Mg). In some embodiments, the first conductivity-type semiconductor layer 110 may include the first conductivity-type semiconductor layer (110 in FIG. 1) described in FIG. 1.

The second conductivity-type semiconductor layer 140 of the emission layer 100 may be located on the second active layer 130. The second conductivity-type semiconductor layer 140 may include a nitride semiconductor having a composition of n-type InₓAl_{y}Ga_{(1-x-y)}N(0≤x<1, 0≤y<1, 0≤x+y<1), and for example, the n-type impurity may be silicon (Si). For example, the second conductivity-type semiconductor layer 140 may include GaN containing n-type impurities. In some embodiments, the second conductivity-type semiconductor layer 140 may include the first conductivity-type semiconductor layer (110 in FIG. 1) described in FIG. 1.

The first active layer 120a and the second active layer 130a of the emission layer 100 may be arranged between the first conductivity-type semiconductor layer 110 and the second conductivity-type semiconductor layer 140, and may generate certain energy by recombination of electrons and holes.

The first active layer 120a may emit light having a peak wavelength of a first wavelength. The second active layer 130a may emit light having a peak wavelength of a second wavelength that is different from the first wavelength. That is, the first active layer 120a and the second active layer 130a may emit light of different peak wavelengths. The emission layer 100 may emit white light through the first active layer 120a and the second active layer 130a.

In some embodiments, the first wavelength of the first active layer 120a may be in a range of about 425 nm to about 480 nm. The second wavelength of the second active layer 130a may be in a range of about 520 nm to about 600 nm. In some embodiments, the first active layer 120a may emit blue light and the second active layer 130a may emit yellow light. In some embodiments, the first active layer 120a may include the first active layer (120 of FIG. 1) described with reference to FIG. 1. In some embodiments, the second active layer 130a may include the second active layer (130 of FIG. 1) described with reference to FIG. 1.

The light-emitting device 10d may emit white light through the first active layer 120a and the second active layer 130a which emit light having different peak wavelengths. That is, the light-emitting device 10d may emit white light without a phosphor. The light-emitting device 10d may be reduced in size without being limited by a phosphor process. As the size of the light-emitting device 10d is reduced, the number of light-emitting devices 10d to be arranged within the same area may be increased. There is no reduction in the contrast ratio as the size of the light-emitting device 10d is reduced, and thus, the image quality may be improved.

Each emission layer 100 may have a first length L1 in the first direction D1 and a second length L2 in a second direction D2 perpendicular to the first direction D1. For example, in each emission layer 100, the first length L1 in the first direction D1 may indicate a maximum length of the emission layer 100 in the first direction D1, and the second length L2 in the second direction D2 may indicate a maximum length of the emission layer 100 in the second direction D2. In some embodiments, the first length L1 of each emission layer 100 may be in a range of about 0.1 μm to about 100 μm, and the second length L2 of each emission layer 100 may be in a range of about 0.1 μm to about 100 μm. In some embodiments, when the area of the upper surface of the emission layer 100 is larger than the area of the lower surface thereof, a length of the upper surface of the emission layer 100 in the first direction D1 may be in a range of about 0.1 μm to about 100 μm, and a length of the upper surface of the emission layer 100 in the second direction D2 may be in a range of about 0.1 μm to about 100 μm.

The plurality of emission layers 100 may be spaced apart from each other by a third distance L3 in the first direction D1. In some embodiments, the third distance L3 may be in a range of about 1 μm to about 15 μm. The reflective layer 300 may be located in a space in which the plurality of emission layers 100 are spaced apart from each other.

The light-emitting device array 20 may include a large number of light-emitting devices 10d in the same area as distances between the plurality of emission layers 100 are reduced, and the size of each emission layer 100 is reduced. As the number of light-emitting devices 10d increases, the contrast ratio of the light-emitting device array 20 may also increase.

The passivation layer 200 of the light-emitting device array 20 may be located on the side surfaces and the lower surface of the emission layer 100. As the passivation layer 200 covers (e.g., at least partially covers, at least partially surrounds, etc.) the side surface of the emission layer 100, a decrease in the light extraction efficiency of the emission layer 100 may be prevented. According to embodiments, the passivation layer 200 may prevent non-emission recombination from occurring in the first active layer 120 or the second active layer 130. In some embodiments, the passivation layer 200 may include the passivation layer of FIG. 1 (200 of FIG. 1).

The reflective layer 300 of the light-emitting device array 20 may be located on the side surfaces of the emission layer 100. The reflective layer 300 may cover (e.g., at least partially cover, at least partially surrounds, etc.) side surfaces of the emission layer 100. In some embodiments, the reflective layer 300 may cover (e.g., at least partially cover, at least partially surrounds, etc.) an entire side surface of the emission layer 100. That is, the upper surface of the reflective layer 300 may be higher than the upper surfaces of the first active layer 120 and the second active layer 130 of the emission layer 100, and thus, light emitted from the first active layer 120 and the second active layer 130 may be reflected by the upper surface of the reflective layer 300. In some embodiments, the reflective layer 300 may be located on the side surfaces and the lower surface of the emission layer 100 to reflect light emitted from the emission layer 100 to the upper surface of the emission layer 100. In some embodiments, the reflective layer 300 may include the reflective layer of FIG. 1 (300 of FIG. 1).

The reflective layer 300 may be located on each of the side surfaces of the plurality of emission layers 100. The reflective layer 300 may extend along each of the side surfaces of the plurality of emission layers 100. In some embodiments, the reflective layer 300 may be located in a space where the plurality of emission layers 100 are spaced apart from each other. In some embodiments, the reflective layer 300 may fill the spaces between the plurality of emission layers 100. In some embodiments, the reflective layer 300 may be arranged between two adjacent emission layers 100 in the first direction D1 or the second direction D2. The reflective layer 300 may prevent optical interference occurring between the plurality of emission layers 100. That is, the reflective layer 300 may reflect light emitted from the emission layer 100, toward the upper surface of the emission layer 100, thereby preventing emission of the light to other adjacent emission layers 100.

The plurality of first electrodes 410 of the light-emitting device array 20 may contact a plurality of different first conductivity-type semiconductor layers 110. In some embodiments, the first electrode 410 may be disposed on the lower surface of the first conductivity-type semiconductor layer 110. The passivation layer 200 may be arranged between the first electrode 410 and the second electrode 420 on the lower surface of the first conductivity-type semiconductor layer 110, and may electrically insulate the first electrode 410 from the second electrode 420. In some embodiments, the plurality of first electrodes 410 may include the first electrode of FIG. 1 (410 of FIG. 1).

The plurality of second electrodes 420 of the light-emitting device array 20 may contact a plurality of different second conductivity-type semiconductor layers 140. In some embodiments, the second electrode 420 may be arranged to be connected to the second conductivity-type semiconductor layer 140 in an opening penetrating the first active layer 120, the second active layer 130, and the first conductivity-type semiconductor layer 110. The first insulating layer 421 may be disposed on an inner wall of the opening to electrically insulate the second electrode 420 from the first active layer 120, the second active layer 130, and the first conductivity-type semiconductor layer 110. In some embodiments, the plurality of second electrodes 420 may include the second electrode (420 in FIG. 1) of FIG. 1.

In some embodiments, the plurality of first electrodes 410 and the plurality of second electrodes 420 may contact the plurality of emission layers 100, respectively. Heights of positions P_410 where the plurality of first electrodes 410 respectively contact the plurality of emission layers 100 may be the same or substantially the same as each other (e.g., a same first height). Heights of positions P_420 where the plurality of second electrodes 420 respectively contact the plurality of emission layers 100 may be the same or substantially the same as each other (e.g., a same second height). That is, the heights of the positions P_410 and P_420 where each of the plurality of emission layers 100 contacts the first electrode 410 or the second electrode 420 may be the same as each other.

In a manufacturing process of the light-emitting device array 20 according to some embodiments, the first conductivity-type semiconductor layer 110 may be formed on a substrate. In some embodiments, by forming a buffer layer on the substrate before forming the first conductivity-type semiconductor layer 110, the first conductivity-type semiconductor layer 110 may be uniformly formed. Next, the first active layer 120a, the second active layer 130a, and the second conductivity-type semiconductor layer 140 may be sequentially formed on the first conductivity-type semiconductor layer 110. In some embodiments, the second active layer 130a, the first active layer 120a, and the second conductivity-type semiconductor layer 140 may be sequentially formed on the first conductivity-type semiconductor layer 110.

The first conductivity-type semiconductor layer 110, the first active layer 120a, the second active layer 130a, and the second conductivity-type semiconductor layer 140 may be etched such that the emission layers 100 have the first length L1 in the first direction D1 and the second length L2 in the second direction D2. Through the etching process, a plurality of emission layers having the first length L1 and the second length L2 may be formed. In other words, the first active layer 120a and the second active layer 130a may be separated from each other. After the etching process is performed, the plurality of emission layers 100 may be spaced apart from each other by the third distance L3. In some embodiments, the etching process starts with the first conductivity-type semiconductor layer 110, and the emission layer 100 may have a tapered shape having an area widening toward the upper surface of the emission layer 100.

The passivation layer 200 and the first electrode 410 may be formed on the emission layer 100. In some embodiments, the passivation layer 200 may be formed to cover the lower and side surfaces of the emission layer 100. A portion of the passivation layer 200 located on the lower surface of each of the plurality of emission layers 100 may be etched to form the first electrode 410. In some embodiments, a trench may be formed on a lower surface of the passivation layer 200 through patterning, and the first electrode 410 may be formed inside the trench.

The first insulating layer 421 and the second electrode 420 may be formed. In some embodiments, a trench penetrating the passivation layer 200, the first conductivity-type semiconductor layer 110, the first active layer 120, and the second active layer 130 may be formed, and the first insulating layer 421 and the second electrode 420 may be formed inside the trench. The second electrode 420a may be electrically connected to the second conductivity-type semiconductor layer 140.

The reflective layer 300 surrounding the side surfaces of the plurality of emission layers 100 may be formed. In some embodiments, the reflective layer 300 may be formed on the passivation layer 200 surrounding the emission layer 100. The reflective layer 300 may include metal such as Al or Ag. In some embodiments, the reflective layer 300 may be formed using an oxide layer stacking method. The passivation layer 200 and the reflective layer 300 may be located between the plurality of emission layers 100 that are spaced apart from each other.

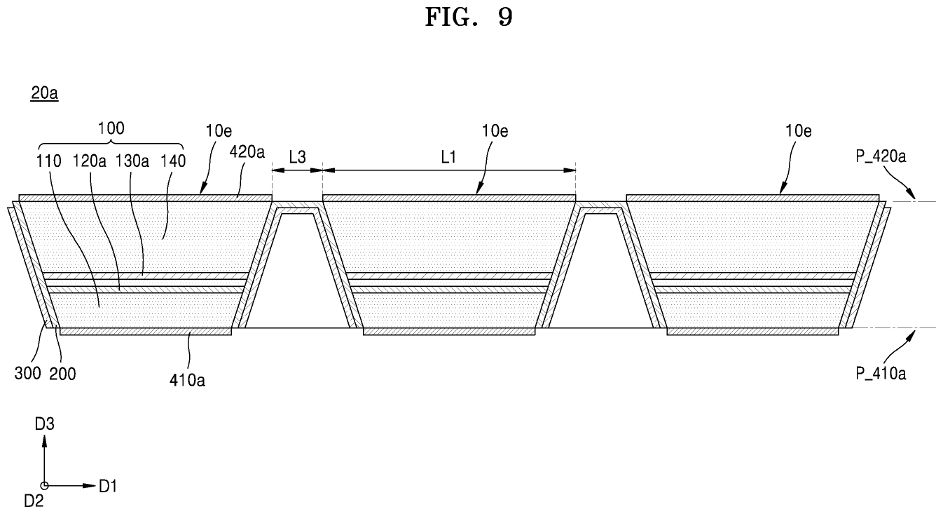

FIG. 9 is a cross-sectional view of a light-emitting device array according to an embodiment.

Referring to FIG. 9, the light-emitting device array 20a of FIG. 9 may include similar aspects as those of the light-emitting device array of FIG. 7 (20 in FIG. 7) and repeated descriptions may be omitted

A plurality of first electrodes 410a of the light-emitting device array 20a may contact the emission layer 100. The first electrode 410a may contact with the first conductivity-type semiconductor layer 110. In some embodiments, the first electrode 410a may contact the whole area of the lower surface of the first conductivity-type semiconductor layer 110.

A plurality of second electrodes 420a of the light-emitting device array 20a may contact the emission layer 100. The second electrode 420a may contact the second conductivity-type semiconductor layer 140. In some embodiments, the second electrode 420a may contact the whole area of the upper surface of the second conductivity-type semiconductor layer 140.

In FIG. 9, the first electrode 410a contacting the first conductivity-type semiconductor layer 110 over the whole area and the second electrode 420a contacting the second conductivity-type semiconductor layer 140 over the whole area are illustrated, but the disclosure is not limited thereto, and only one of the first electrode 410a or the second electrode 420a may contact a conductivity-type semiconductor layer over the whole area, or a partial area may be contacted as is described above.

The first electrode 410a may contact the lower surface of the first conductivity-type semiconductor layer 110 and electrically connected to the first conductivity-type semiconductor layer 110. The second electrode 420a may contact the upper surface of the second conductivity-type semiconductor layer 140 and be electrically connected to the second conductivity-type semiconductor layer 140. The second electrode 420a may be configured to transmit through light emitted from the emission layer 100. That is, the second electrode 420a may be substantially transparent to the light emitted from the emission layer 100. For example, the second electrode 420a may include indium tin oxide (ITO). The light emitted from the emission layer 100 may pass through the second electrode 420a and be emitted to the outside. As the second electrode 420a is located on the upper surface of the second conductivity-type semiconductor layer 140, the manufacture of a light-emitting device 10f may be facilitated.

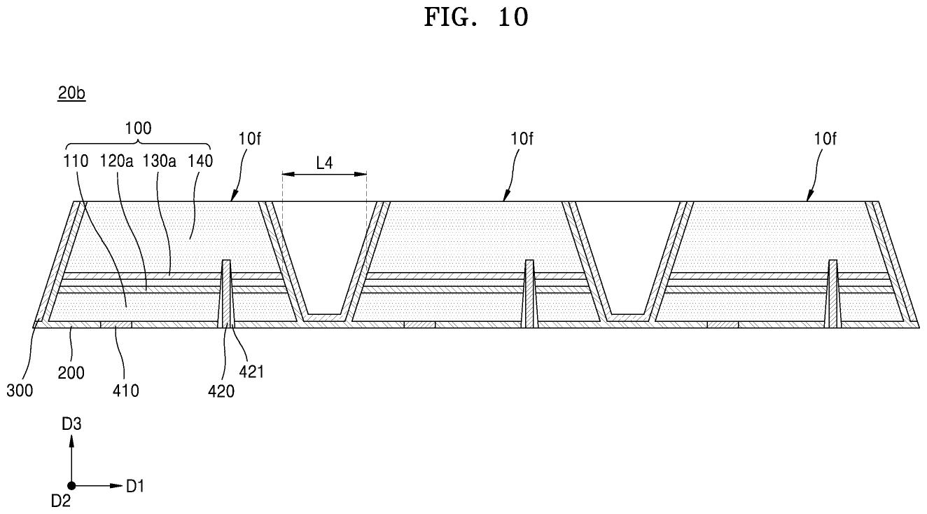

FIG. 10 is a cross-sectional view of a light-emitting device array according to an embodiment.

Referring to FIG. 10, the light-emitting device array 20b of FIG. 10 may include similar aspects as those of the light-emitting device array of FIG. 7 (20 in FIG. 7), and repeated descriptions may be omitted.

The plurality of emission layers 100 of the light-emitting device array 20b may have a width varying toward an upper surface thereof. In some embodiments, the emission layer 100 may have a tapered shape having a width increasing toward an upper surface thereof. In some embodiments, the emission layer 100 may have a tapered shape having a width decreasing toward an upper surface thereof. In some embodiments, in a process of etching the side surfaces of the emission layer 100, the side surfaces of the emission layer 100 may be inclined. In some embodiments, in a process of etching the side surfaces of the emission layer 100, the side surfaces of the emission layer 100 may be perpendicular to the upper and lower surfaces of the emission layer 100.

In some embodiments, when etching is performed on the upper surface of the emission layer 100, the emission layer 100 may have a shape in which the upper surface has a smaller area than the lower surface. When etching is performed on the upper surface of the emission layer 100, an angle formed between the side surfaces and the lower surface of the emission layer 100 may be in a range of about 60 degrees to about 70 degrees. When etching is performed on the upper surface of the emission layer 100, portions of the first active layer 120 and the second active layer 130 to be removed may be reduced. As the first active layer 120a and the second active layer 130a of the emission layer 100 have a relatively wide area, the light-emitting device 10b may have relatively high contrast ratio and brightness.

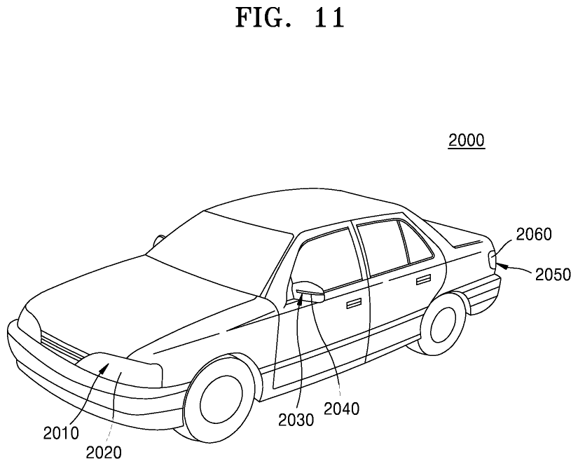

FIG. 11 is a diagram of a lighting device including a light-emitting device according to an embodiment.

Referring to FIG. 11, a head lamp module 2020 may be installed in a head lamp unit 2010 of a vehicle, and a side mirror lamp module 2040 may be installed in an exterior side mirror unit 2030, and a tail lamp module 2060 may be installed in a tail lamp unit 2050. At least one of the head lamp module 2020, the side mirror lamp module 2040, and the tail lamp module 2060 may include at least one of the light-emitting devices 10, 10a, 10b, 10c, and 10d described above.

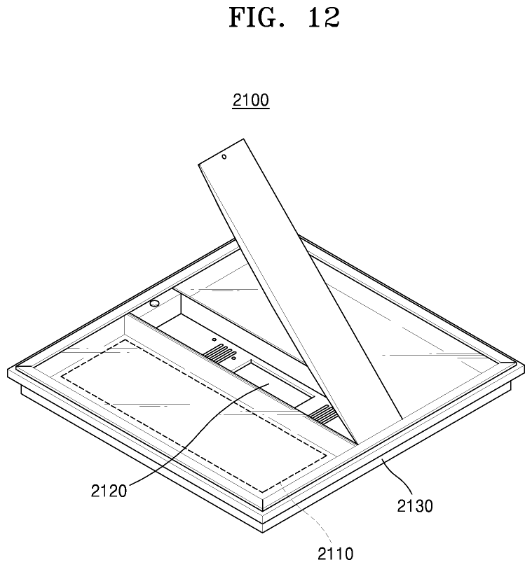

FIG. 12 is a diagram of a flat panel lighting device including a light-emitting device according to an embodiment.

Referring to FIG. 12, a flat panel lighting device 2100 may include a light source module 2110, a power supply device 2120, and a housing 2130. According to an embodiment, the light source module 2110 may include a light-emitting device array as a light source. The light source module 2110 may include at least one of the light-emitting devices 10, 10a, 10b, 10c, and 10d described above, as a light source. The power supply device 2120 may include a light-emitting device driver.

The light source module 2110 may include the light-emitting device arrays 20, 20a, and 20b described above, and may be formed to achieve a planar phenomenon as a whole. According to an embodiment, the light-emitting device arrays 20, 20a, and 20b may include a light-emitting device and a controller that stores driving information of the light-emitting device.

The power supply device 2120 may be configured to supply power to the light source module 2110. The housing 2130 may have an accommodation space formed therein to accommodate the light source module 2110 and the power supply device 2120, and is formed in a hexahedral shape with one side open, but is not limited thereto. The light source module 2110 may be disposed to emit light to the one open side of the housing 2130.

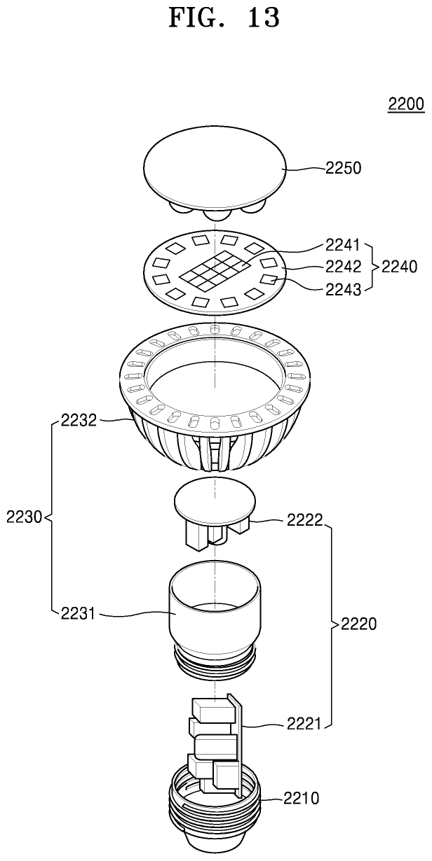

FIG. 13 is a diagram of a lighting device including a light-emitting device according to an embodiment.

A lighting device 2200 may include a socket 2210, a power supply unit 2220, a heat dissipation unit 2230, a light source module 2240, and an optical unit 2250. According to an embodiment, the light source module 2240 may include a light-emitting device array, and the power supply unit 2220 may include a light-emitting device driver.

The socket 2210 may be configured to be replaced with an existing lighting device. Power supplied to the lighting device 2200 may be applied through the socket 2210. As illustrated in the drawing, the power supply unit 2220 may be formed by assembling a first power supply unit 2221 and a second power supply unit 2222 together. The heat dissipation unit 2230 may include an internal dissipation unit 2231 and an external dissipation unit 2232, and the internal dissipation unit 2231 may be directly connected to the light source module 2240 and/or the power supply unit 2220, and accordingly, heat may be transferred to the external heat dissipation unit 2232. The optical unit 2250 may include an internal optical unit and an external optical unit, and may be configured to evenly disperse light emitted from the light source module 2240.

The light source module 2240 may receive power from the power supply unit 2220 and emit light to the optical unit 2250. The light source module 2240 may include one or more light-emitting device packages 2241, a circuit board 2242, and a controller 2243, and the controller 2243 may store driving information of the light-emitting device package 2241. The light source module 2110 may include at least one of the light-emitting devices 10, 10a, 10b, 10c, and 10d described above, as a light source.

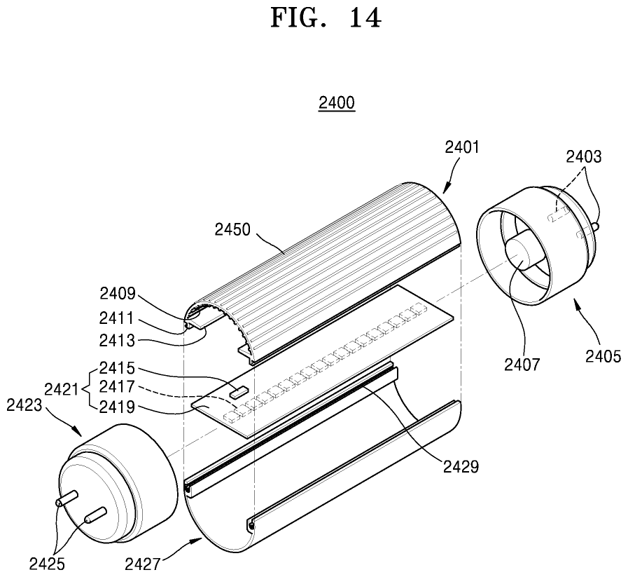

FIG. 14 is a diagram of a bar-type lighting device including a light-emitting device according to an embodiment.

The lighting device 2400 includes a heat dissipation member 2401, a cover 2427, a light source module 2421, a first socket 2405, and a second socket 2423. A plurality of heat dissipation fins 2450 and 2409 may be formed in a concavo-convex shape on an inner or/or outer surface of the heat dissipation member 2401, and the heat dissipation fins 2450 and 2409 may be designed to have various shapes and intervals. A support 2413 having a protruding shape is formed inside the heat dissipation member 2401. A light source module 2421 may be fixed to the support 2413. Locking protrusions 2411 may be formed at both ends of the heat dissipation member 2401.

A locking groove 2429 may be formed in the cover 2427, and the locking protrusions 2411 of the heat dissipation member 2401 may be coupled to the locking groove 2429 in a hook coupling structure. Positions where the locking groove 2429 and the locking protrusions 2411 are formed may be interchanged.

The light source module 2421 may include the light-emitting device arrays 20, 20a, and 20b described above. The light source module 2421 may include a printed circuit board 2419, a light source 2417, and a controller 2415. The controller 2415 may store driving information of the light source 2417. Circuit wires for operating the light source 2417 are formed on the printed circuit board 2419. Also, components for operating the light source 2417 may be included. The light source 2417 may include at least one of the light-emitting devices 10, 10a, 10b, 10c, and 10d.

The first and second sockets 2405 and 2423 are a pair of sockets and have a structure coupled to both ends of a cylindrical cover unit including a heat dissipation member 2401 and a cover 2427. For example, the first socket 2405 may include electrode terminals 2403 and a power supply device 2407, and dummy terminals 2425 may be arranged on the second socket 2423. In addition, an optical sensor and/or a communication module may be embedded in any one of the first socket 2405 and the second socket 2423. For example, an optical sensor and/or a communication module may be embedded in the second socket 2423 on which the dummy terminals 2425 are arranged. As another example, an optical sensor and/or a communication module may be embedded in the first socket 2405 where the electrode terminals 2403 are arranged.

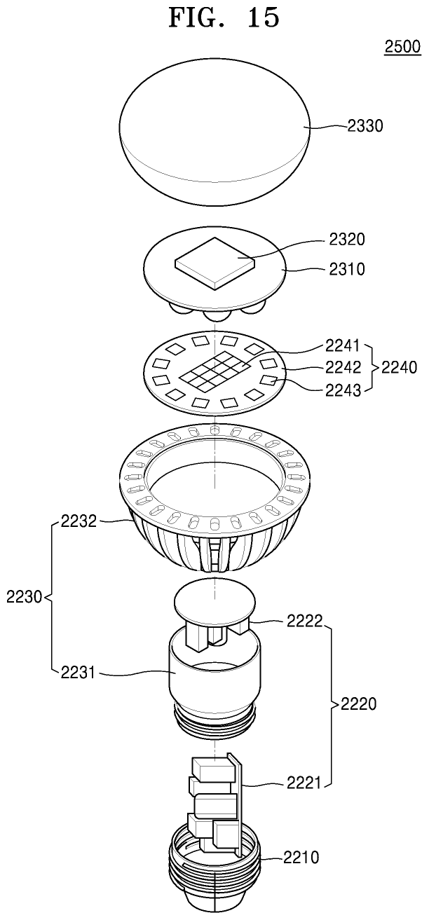

FIG. 15 is a diagram of a lighting device including a semiconductor light-emitting device according to an embodiment.

A difference between a lighting device 2500 and the lighting device 2200 described above is that a reflector 2310 and a communication module 2320 are included above the light source module 2240. The reflector 2310 may reduce glare by evenly spreading light from a light source to the side and rear.

A communication module 2320 may be mounted on the reflector 2310, and through the communication module 2320, home-network communication may be implemented. For example, the communication module 2320 may include a wireless communication module using Zigbee, WiFi, or LiFi, and may control lights installed inside and outside the home, such as on/off, brightness control, or the like, through a smartphone or a wireless controller. In addition, by using a Li-Fi communication module using visible light wavelengths of lighting devices installed inside and outside the home, electronic products and automobile systems inside and outside the home, such as TVs, refrigerators, air conditioners, door locks, and automobiles may be controlled. The reflector 2310 and the communication module 2320 may be covered by a cover portion 2330.

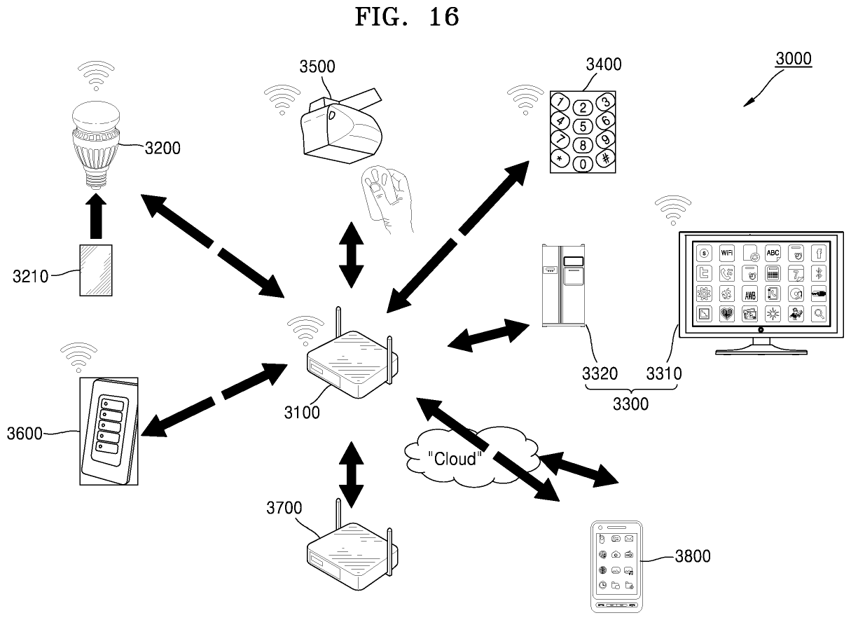

FIG. 16 is a diagram of a control network system for an indoor lighting device including a semiconductor light-emitting device according to embodiments.

In detail, a network system 3000 may include a complex smart lighting-network system in which lighting technology using a light-emitting device such as a light-emitting diode (LED), is converged with Internet of Things (IoT) technology, wireless communication technology, etc. The network system 3000 may be implemented using various lighting devices and wired/wireless communication devices, and may be implemented by sensors, controllers, communication means, and software for network control and maintenance.

The network system 3000 may be applied to open spaces such as parks and streets as well as closed spaces defined in buildings such as homes and offices. The network system 3000 may be implemented based on the Internet of Things (IoT) environment so that various types of information may be collected/processed and provided to users.

An LED lamp 3200 included in the network system 3000 may control the lighting of the LED lamp 3200 itself by receiving information about the surrounding environment from the gateway 3100, as well as perform a function of checking and controlling the operation status of other devices 3300 to 3800 included in the IoT environment, based on the function of the visible light communication of the LED lamp 3200. The LED lamp 3200 may include at least one of the light-emitting devices 10, 10a, 10b, 10c, and 10d described above.

The network system 3000 may include a gateway 3100 for processing data transmitted and received according to different communication protocols, the LED lamp 3200 communicatively connected to the gateway 3100 and including an LED light-emitting device, and a plurality of devices 3300 to 3800 communicatively connected to the gateway 3100 according to various wireless communication methods. Each of the devices 3300 to 3800, including the LED lamp 3200, may include at least one communication module, and the LED lamp 3200 may be communicatively connected to the gateway 3100, by using a wireless communication protocol such as WiFi, Zigbee, or LiFi, and may have at least one communication module 3210 for lamp, for this purpose.

When the network system 3000 is applied to a home, the plurality of devices 3300 to 3800 may include a home appliance 3300, a digital door lock 3400, a garage door lock 3500, a light switch 3600 installed on a wall, a router 3700 for relaying a wireless communication network, and a mobile device 3800 such as a smartphone, tablet, or laptop computer.

In the network system 3000, the LED lamp 3200 may check the operation status of the various devices 3300 to 3800 by using a wireless communication network (Zigbee, WiFi, LiFi, etc.) installed in the home, or may adjust the illuminance of the LED lamp 3200 itself according to the ambient environment or situation. In addition, the devices 3300 to 3800 included in the network system 3000 may be controlled using LiFi communication using visible light emitted from the LED lamp 3200.

First, the LED lamp 3200 may automatically adjust the illuminance of the LED lamp 3200 based on the surrounding environment information transmitted from the gateway 3100 through the lamp communication module 3210 or the surrounding environment information collected from a sensor mounted on the LED lamp 3200. For example, the brightness of the LED lamp 3200 may be automatically adjusted according to the type of program being broadcast on a television 3310 or the brightness of the screen. To this end, the LED lamp 3200 may receive operation information of the television 3310 from the lamp communication module 3210 connected to the gateway 3100. The lamp communication module 3210 may be integrally modularized with a sensor and/or a controller included in the LED lamp 3200.

For example, when a certain period of time elapses after the digital door lock 3400 is locked in a state in which no one is present in the home, all of turned-on LED lamps 3200 may be turned off to prevent waste of electricity. Alternatively, when a security mode is set through the mobile device 3800 or the like, when the digital door lock 3400 is locked when there is no one in the home, the LED lamp 3200 may be maintained in a turned-on state.

The operation of the LED lamp 3200 may be controlled according to the surrounding environment information collected through various sensors connected to the network system 3000. For example, when the network system 3000 is implemented in a building, lightings, location sensors, and communication modules are combined in a building to collect location information of people in the building and turn on or turn off lights or provide the collected information in real time to enable facility management or efficient use of idle space. In general, as lighting devices such as the LED lamp 3200 are arranged in almost all spaces on each floor in a building, various information within the building may be collected through sensors provided integrally with the LED lamp 3200, and the information may be used for facility management, or utilization of idle spaces, etc.

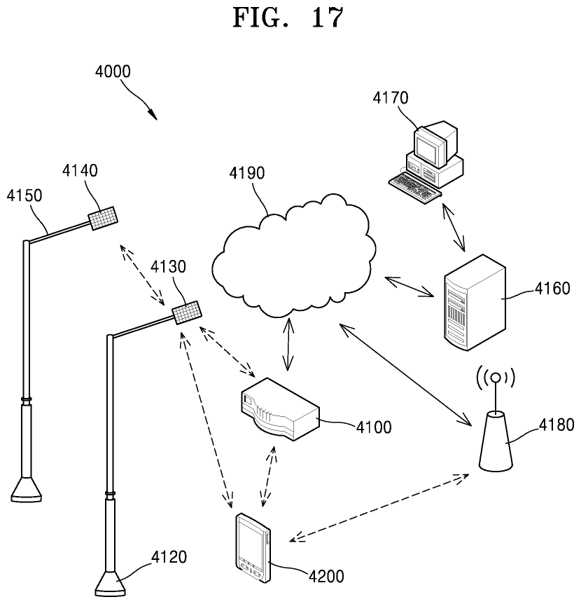

FIG. 17 is a diagram of a network system including a semiconductor light-emitting device according to an embodiment.

FIG. 17 illustrates an embodiment of a network system 4000 applied to an open space. The network system 4000 may include a communication connection device 4100, a plurality of lighting devices 4120 and 4150 installed at certain intervals and connected to communicate with the communication connection device 4100, a server 4160, a computer 4170 for managing the server 4160, a communication base station 4180, a communication network 4190 connecting communication capable devices, and a mobile device 4200.

Each of the plurality of lighting devices 4120 and 4150 installed in an open external space such as a street or a park may include smart engines 4130 and 4140. The smart engines 4130 and 4140 may include a light-emitting device for emitting light and a driving driver for driving the light-emitting device, as well as a sensor for collecting information on the surrounding environment, and a communication module. The light-emitting device included in a smart engine may include at least one of the light-emitting devices 10, 10a, 10b, 10c, and 10d.

Through the communication module, the smart engines 4130 and 4140 may communicate with other peripheral devices according to communication protocols such as WiFi, Zigbee, and LiFi. One smart engine 4130 may be communicatively connected to another smart engine 4140, and WiFi expansion technology (WiFi Mesh) may be applied to communication between the smart engines 4130 and 4140. At least one smart engine 4130 may be connected to the communication connection device 4100 connected to the communication network 4190 through wired/wireless communication.

The communication connection device 4100 is an access point that allows wired/wireless communication, and may mediate communication between the communication network 4190 and other equipment. The communication connection device 4100 may be connected to the communication network 4190 by at least one of a wired/wireless method, and may be mechanically housed in one of the lighting devices 4120 and 4150, for example.

The communication connection device 4100 may be connected to the mobile device 4200 through a communication protocol such as WiFi. A user of the mobile device 4200 may receive the surrounding environment information collected by the plurality of smart engines 4130 and 4140 (e.g., surrounding traffic information, weather information, etc.), by using the communication connection device 4100 connected to the smart engine 4130 of the lighting device 4120 in the vicinity. The mobile device 4200 may be connected to the communication network 4190 through a communication base station 4180 through a wireless cellular communication method such as 3^{rd} generation (3G), 4^{th} generation (4G), 5^{th} generation (5G), etc.

On the other hand, the server 4160 connected to the communication network 4190 may receive the information collected by the smart engines 4130 and 4140 mounted on each of the lighting devices 4120 and 4150, and may monitor each of the lighting devices 4120, 4150 at the same time. The server 4160 may be connected to a computer 4170 providing a management system, and the computer 4170 may execute software capable of monitoring and managing operating states of the smart engines 4130 and 4140.

In the light-emitting device according to example, white light may be emitted without a phosphor, and thus, more light-emitting devices may be located in the same size. Thus, optical interference between adjacent light-emitting devices may be suppressed, thereby improving the contrast ratio.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A light-emitting device comprising:
an emission layer configured to emit white light; and
a reflective layer at least partially surrounding side surfaces of the emission layer;
wherein the emission layer comprises:
a first conductivity-type semiconductor layer;
a second conductivity-type semiconductor layer on the first conductivity-type semiconductor layer;
a first active layer between the first conductivity-type semiconductor layer and the second conductivity-type semiconductor layer, the first active layer configured to emit blue light; and
a second active layer between the first conductivity-type semiconductor layer and the second conductivity-type semiconductor layer, the second active layer configured to emit yellow light.

2. The light-emitting device of claim 1, wherein a peak wavelength of the blue light is between about 425 nm and about 480 nm, and
wherein a peak wavelength of the yellow light is between about 520 nm and about 600 nm.

3. The light-emitting device of claim 1, wherein the second active layer is on the first active layer.

4. The light-emitting device of claim 1, wherein the second active layer comprises a quantum well layer, a quantum barrier layer, and an intermediate lattice layer,
wherein the quantum well layer comprises indium gallium nitride,
wherein the quantum barrier layer comprises aluminum gallium nitride,
wherein the intermediate lattice layer is between the quantum well layer and the quantum barrier layer, and
wherein the intermediate lattice layer comprises indium gallium nitride or aluminum gallium nitride.

5. The light-emitting device of claim 4, wherein the quantum well layer has a thickness of about 3 nm to about 7 nm,
wherein the quantum barrier layer has a thickness of about 1 nm to about 10 nm, and
wherein the intermediate lattice layer has a thickness of about 1 nm to about 5 nm.

6. The light-emitting device of claim 1, further comprising:
a first electrode contacting the first conductivity-type semiconductor layer; and
a second electrode contacting the second conductivity-type semiconductor layer.

7. The light-emitting device of claim 6, further comprising an opening penetrating each of the first conductivity-type semiconductor layer, the first active layer, and the second active layer,
wherein the second electrode is connected to the second conductivity-type semiconductor layer within the opening.

8. The light-emitting device of claim 6, wherein the second electrode contacts an upper surface of the second conductivity-type semiconductor layer, and
wherein light emitted from the emission layer is transmitted through the second electrode.

9. The light-emitting device of claim 1, wherein the reflective layer surrounds an entire area of the side surfaces of the emission layer.

10. The light-emitting device of claim 1, wherein the reflective layer is on a lower surface of the emission layer.

11. A light-emitting device array comprising:
a plurality of emission layers spaced apart from each other in a first direction, each of the plurality of emission layers being configured to emit white light; and
a reflective layer at least partially surrounding side surfaces of the plurality of emission layers,
wherein each of the plurality of emission layers comprises:
a first conductivity-type semiconductor layer;
a second conductivity-type semiconductor layer on the first conductivity-type semiconductor layer;
a first active layer between the first conductivity-type semiconductor layer and the second conductivity-type semiconductor layer, the first active layer configured to emit light having a first peak wavelength; and
a second active layer between the first conductivity-type semiconductor layer and the second conductivity-type semiconductor layer, the second active layer configured to emit light having a second peak wavelength that is different from the first peak wavelength.

12. The light-emitting device array of claim 11, wherein each of the plurality of emission layers have a first length in the first direction and a second length in a second direction perpendicular to the first direction,
wherein the first length is about 0.1 μm to about 100 μm, and
wherein the second length is about 0.1 μm to about 100 μm.

13. The light-emitting device array of claim 11, wherein the plurality of emission layers are spaced apart from each other in the first direction by about 1 μm to about 15 μm.

14. The light-emitting device array of claim 11, further comprising:
a plurality of first electrodes each contacting different emission layers among the plurality of emission layers; and
a plurality of second electrodes each contacting different emission layers among the plurality of emission layers,
wherein the plurality of first electrodes contact the first conductivity-type semiconductor layer, and
wherein the plurality of second electrodes contact the second conductivity-type semiconductor layer.

15. The light-emitting device array of claim 14, wherein positions at which the plurality of first electrodes respectively contact the plurality of emission layers are of a same first height, and
wherein positions at which the plurality of second electrodes respectively contact the plurality of emission layers are of a same second height.

16. The light-emitting device array of claim 11, wherein the first peak wavelength is about 425 nm to about 480 nm, and
wherein the second peak wavelength is about 520 nm to about 600 nm.

17. The light-emitting device array of claim 11, wherein a width of each of the plurality of emission layers increases toward an upper surface of the light-emitting device array.

18. The light-emitting device array of claim 11, wherein the reflective layer is between two adjacent emission layers of the plurality of emission layers.

19. The light-emitting device array of claim 11, wherein the reflective layer surrounds an entire area of the side surfaces of the plurality of emission layers.

20. A light-emitting device array comprising:
a plurality of emission layers spaced apart from each other in a first direction, each of the plurality of emission layers comprising:
a first conductivity-type semiconductor layer,
a first active layer configured to emit blue light,
a second active layer configured to emit yellow light, and
a second conductivity-type semiconductor layer,
wherein the first conductivity-type semiconductor layer, the first active layer, the second active layer and the second conductivity-type semiconductor layer are sequentially stacked;
a reflective layer at least partially surrounding side surfaces of the plurality of emission layers;
a plurality of first electrodes each contacting different emission layers among the plurality of emission layers; and
a plurality of second electrodes each contacting different emission layers among the plurality of emission layers,
wherein each of the plurality of emission layers has a length of about 0.1 μm to about 100 μm in the first direction, and a length of about 0.1 μm to about 100 μm in a second direction perpendicular to the first direction,
wherein the plurality of emission layers are spaced apart from each other in the first direction by about 1 μm to about 15 μm,
wherein positions at which the plurality of first electrodes respectively contact the plurality of emission layers are of a same first height, and
positions at which the plurality of second electrodes respectively contact the plurality of emission layers are of a same second height.
